(19) United States
(12) Patent Application Publication
(10) Pub. No.: US 2006/0003580 A1
(43) Pub. Date: Jan. 5, 2006

(54) Under bump metallurgy process on passivation opening

(76) Inventors: Hun Song Goh, Bayan Lepas (MY); Mohd Erwan Basiron, Perai (MY)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/881,490

(22) Filed: Jun. 30, 2004

(51) Int. Cl. H01L 21/44

(52) U.S. Cl. 438/652

(57) ABSTRACT

A method including electrodepositing a metal layer on a contact pad of a circuit, wherein the metal layer protrudes from the contact pad and has a width dimension greater than a width dimension of the pad. A method including forming a first layer on a contact pad in a contact opening in a dielectric layer; and electrodepositing a second layer directly on the first layer, the electrodepositing being of sufficient duration to protrude from the contact opening. An apparatus including an integrated circuit comprising a plurality of contact pads formed in contact openings in a dielectric material on the surface of the integrated circuit; and an electrodeposited layer formed individually each of the plurality of contact pads, each electrodeposited layer extending from the respective contact opening.

### BACKGROUND

1. Field

Integrated circuit packaging.

2. Background

Integrated circuit chips or die are typically assembled into a package that is soldered to a printed circuit board. A chip or die may have contacts on one surface that are used to electrically connect the chip or die to the package substrate and correspondingly an integrated circuit to the package substrate. Accordingly, a suitable package substrate may have corresponding contacts on one surface. One way a number of contacts of a chip or die are connected to contacts of a package substrate are through solder ball contacts in, for example, a controlled collapse chip connect (C4) process.

A typical solder material is a lead-based material. One concern of lead-based materials are the environmental consequences of lead, including health risks. Accordingly, efforts are being made to reduce or eliminate the use of lead-based materials.

In the selection of any solder material to electrically connect (through contacts), a chip or die to a package substrate, is the ability to withstand the stress of the connection. A package substrate may be constructed from a composite material that has a coefficient of thermal expansion (CTE) that is different than a coefficient of thermal expansion of the chip or die. Variations in temperature, including heating as part of a reflow process to connect the chip to the package through the solder, may cause a resultant differential expansion between the chip and the package substrate. The differential expansion may induce stresses (e.g., sheer stresses) that can crack the connections between the chip and the package substrate (e.g., crack one or more solder bumps). The connections carry electrical current between the chip and the package substrate so that any crack in the connects may affect the operation in the circuit.

### BRIEF DESCRIPTION OF THE DRAWINGS

Features, aspects, and advantages of embodiments will become more thoroughly apparent from the following detailed description, appended claims, and accompanying drawings in which:

FIG. 1 shows a package connected to a circuit board.

FIG. 2 shows a portion of an integrated circuit chip including contact points with contact openings and a seed layer on the contact points.

FIG. 3 shows the chip of FIG. 2 after the deposition of an under bump metal (UBM) layer on the seed layer.

FIG. 4 shows the structure of FIG. 3 after the deposition of an adhesion layer on the under bump metal layer.

FIG. 5 shows the structure of FIG. 4 after the deposition of a solder material on the adhesion layer.

### DETAILED DESCRIPTION

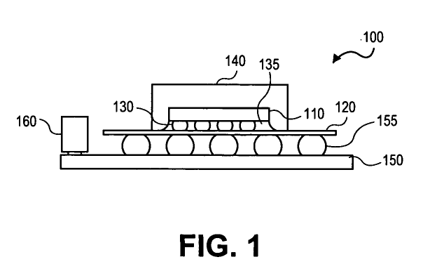

FIG. 1 shows an embodiment of an electronic assembly including a package connected to a printed circuit board (PCB). The electronic assembly may be part of an electronic system such as a computer (e.g., desktop, laptop, hand-held, server, Internet appliance, etc.), a wireless communication device (e.g., cellular phone, cordless phone, pager), a computer-related peripheral (e.g., printer, scanner, monitor), an entertainment device (e.g., television, radio, stereo, tape player, compact disk player, video cassette recorder, MP3 (Motion Picture Experts Group, Audio Layer 3 player) and the like.

In the embodiment shown in FIG. 1, electronic assembly 100 includes chip or die 110, having a number of circuit devices formed thereon and therein, connected to package substrate 120. Chip 110 is electrically connected to a package substrate 120, in this embodiment, through lead-free solder material 130 (shown as solder balls) between corresponding contact pads on chip 110 and package substrate 120, respectively. Electronic assembly 100 includes underfill formulation 135 disposed between chip 110 and package substrate 135 and molding compound 140 formed over chip 110 and package substrate 120.

FIG. 1 shows package substrate 120 connected to printed circuit board (PCB) 150. PCB is, for example, a motherboard or other circuit board. Package substrate 120 is connected to PCB 150 through connections 155 such as lead-free solder connections. PCB 150 may include other components, possibly connected to chip 110 through traces embedded in PCB 150. Representatively, FIG. 1 shows unit 160 that is, for example, a memory device, a power source device or other device.

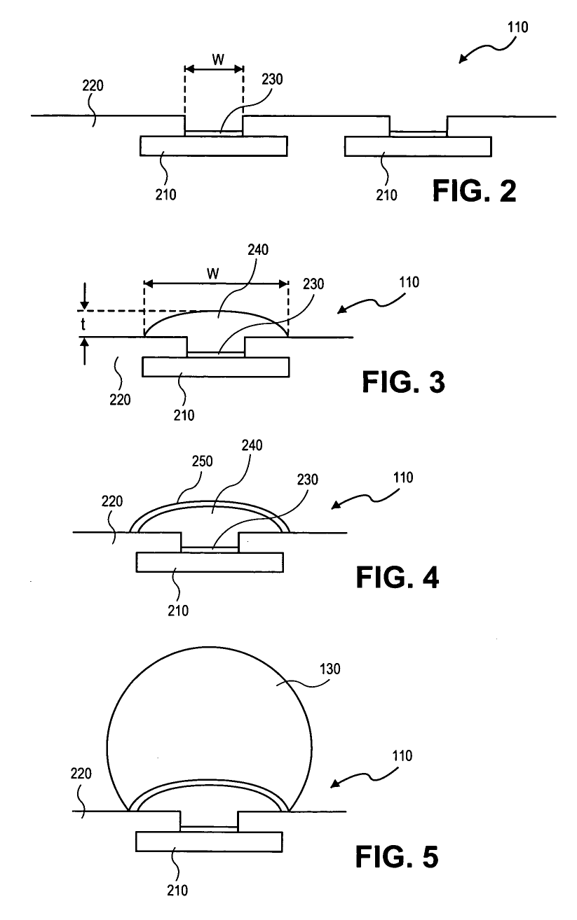

FIG. 2 shows a magnified view of a portion of a surface of chip 110 from FIG. 1. Relative to FIG. 1, chip 110 is inverted (flipped) in FIG. 2. Specifically, FIG. 2 shows contact pads that are, for example, connected to circuitry within the chip. Disposed over contact pads 210 is passivation layer 220, such as a polyimide material or other dielectric material. FIG. 2 shows contact openings 230 in passivation layer 220 to contact pads 210. According to one current design rule, openings 230 have length and width dimensions on the order of about 40 microns. FIG. 2 illustrates, for example, the width, w, of a contact opening.

In one embodiment, an under bump metal (UBM) layer will be formed on contact pads 210. In one embodiment, an under bump metal layer will be electrodeposited onto contact pad 210. To facilitate the electrodeposition of a UBM layer, in one embodiment, a seed layer is first deposited on the contact pad. FIG. 2 shows seed layer 230 of, for example, palladium deposited on contact pad 210. A seed layer of a palladium material may be sputter deposited on contact pads 210 to a thickness on the order of a few microns (e.g., approximately 5 microns).

FIG. 3 shows the structure of FIG. 2 following the electrodeposition of a UBM layer. UBM layer 240, in one embodiment, is formed by an electroplating process. A suitable material for UBM layer 240 in a lead-free solder packaging process is a nickel-gold (NiAu) alloy. An electroplating process involves introducing chip 110 into an aqueous solution containing metal ions, such as nickel ions and gold ions, and reducing the ions (reducing the oxidation number) to a metallic state by applying current between chip 110 with seed layer 230 and an anode of an electroplating cell in the presence of the solution.

Experimental evidence suggests that a UBM layer connected to a contact pad through a 40 micron contact opening needs to have a width dimension, W, on the order to 60 microns to 80 microns to provide the UBM layer and subsequent solder connection with sufficient sheer strength to resist cracking during, for example, a reflow process. A suitable thickness, t, or height of UBM layer 240 to provide UBM layer 240 and a subsequent solder bump with sufficient sheer strength is on the order of 25 microns for a 40 micron contact opening. One way to form a UBM layer having a sufficient structural dimension is to prolong the plating period. FIG. 3 shows UBM layer 240 formed to a desired structural dimension, including width, W, by continuing plating until the desired structural dimension is achieved. Representatively, to achieve a structural dimension having a width on the order of 60 microns to 80 microns on a 40 micron contact pad requires that the plating process be extended approximately three times longer (about two hours plating time) than would ordinarily be the case for plating a UBM layer to fill a via in passivation layer 220.

FIG. 4 shows the structure of FIG. 3 following the deposition of adhesion layer 250 on UBM layer 240. In one embodiment, adhesion layer 250 is a material that provides enhanced adhesion of a lead-free solder material to be connected to the structure. In one embodiment, adhesion layer 250 is a gold (Au) material deposited to a thickness on the order of a few microns.

FIG. 5 shows the structure of FIG. 4 following the deposition of solder material 130. In one embodiment, solder material 130 is a lead-free solder material. An example is tin-silver-copper alloy (SnAgCu) alloy.

Following the deposition of solder material 130 on chip 110, chip 110 may be connected to package substrate 120 by aligning contact pads on package substrate 120 with solder material 130. A reflow process may follow to form a solder joint. A reflow process for a SnAgCu alloy is a peak temperatures of 230° C. (±10° C.), for 60 seconds (±10 seconds), with a soak time of less than about 100 seconds.

In the preceding paragraphs, specific embodiments are described. It will, however, be evident that various modifications and changes may be made thereto without departing from the broader spirit and scope of the claims. The specification and drawings are, accordingly, to be regarded in an illustrative rather than a restrictive sense.

1. A method comprising:
electrodepositing a metal layer on a contact pad of a circuit, wherein the metal layer protrudes from the contact pad and has a width dimension greater than a width dimension of the pad, wherein the contact pad is formed in a contact opening in a dielectric layer defining the width dimension of the pad.

2. (canceled)

3. The method of claim 1, prior to electrodepositing a metal layer, the method further comprising:
prior to electrodepositing the metal layer forming a first seed layer confined to an area of the contact pad.

4. The method of claim 3, wherein electrodepositing comprises electroplating.

5. The method of claim 4, forming a third layer on the second layer.

6. The method of claim 5, wherein each of the first layer, the second layer, and the third layer comprises lead free materials.

7. A method comprising:
forming a first layer on a contact pad in a contact opening in a dielectric layer; and
electrodepositing a second layer directly on the first layer, the electrodepositing being of sufficient duration to protrude from the contact opening.

8. The method of claim 7, wherein the first layer is confined to an area of the contact pad.

9. The method of claim 7, wherein electrodepositing comprises electroplating.

10. The method of claim 8, forming a third layer on the second layer.

11. The method of claim 10, wherein each of the first layer, the second layer, and the third layer comprises lead free materials.

12. An apparatus comprising:
an integrated circuit comprising a plurality of contact pads formed in contact openings in a dielectric material on the surface of the integrated circuit; and
an electrodeposited layer formed individually each of the plurality of contact pads, each electrodeposited layer extending from the respective contact opening

13. The apparatus of claim 12, further comprising a seed layer on each of the plurality of contact pads and confined with the contact openings wherein the seed layer is disposed between the contact pad and the electrodeposited layer.

14. The apparatus of claim 13 further comprising a lead free solder material formed on the electrodeposited layer.

15. The apparatus of claim 12, wherein the electrodeposited layer comprises a thickness suitable to resist a sheer stress anticipated for a reflow process of the solder material.
